(19) United States
(12) Patent Application Publication
(10) Pub. No.: US 2011/0017268 A1
(43) Pub. Date: Jan. 27, 2011

(54) Transparent polymer materials for encapsulation of optical devices and photovoltaic module that uses this polymer

(75) Inventors: Elena M. Shembel, Colar Springs, FL (US); Aleksandra Shmyryeva, Kiev (UA); Tamara Todosiychuk, Kiev (UA); Ludmila Kosyanchuk, Kiev (UA); Volodymyr Redko, Coral Springs, FL (US); Tymofiy V. Pastushkin, Ft. Lauderdale, FL (US)

Correspondence Address: Enerize Corporation, 4956 Rothschild Dr., Coral Springs, FL, 33067-4134, US

(73) Assignee: Enerize Corporation, Coral Springs, FL (US)

(21) Appl. No.: 12/803,953

(22) Filed: Jul. 8, 2010

Related U.S. Application Data
(60) Provisional application No. 61/270,564, filed on Jul. 10, 2009.

(51) Int. Cl. H01L 31/052; B32B 27/40; G02B 1/10; C08L 75/06

(52) U.S. Cl. 136/246; 428/338; 428/423.1; 524/590

(57) ABSTRACT

Flexible optically transparent nano structured polymer material is based on the composition that includes the derivatives of polyurethanes, hardening agent, antistatic additive and modifiers. The structure of polymer includes nano and micro-domains and clusters of various sizes and configurations that are located in a certain order in the volume of the polymer and play the role of micro lenses that provide the concentration of the light and to concentration of light on the optical device and strengthen wave of optical radiation. The transparent polymer laminated, encapsulated or coated of incident light-facing surface of optical devices including the photovoltaic modules and imparts higher conversion efficiencies to photovoltaic modules, a high optical transparency, is resistant to the humidity and destructive effects of UV, has a good adhesion to the surface of the optical devices, and a good stability to deformation. The transparent polymer materials can be used to increase conversion efficiency of mono-crystalline, multi-crystalline and nana-crystalline, as well as amorphous silicon and based on non-silicon systems such as CIGS solar cells, DSSC and organic.

### CROSS-REFERENCE TO RELATED APPLICATIONS

This application incorporates by reference in its entirety and claims priority to Provisional Application No. 61/270,564, Filed Jul. 10, 2009.

### FEDERALLY SPONSORED RESEARCH

None

### SEQUENCE LISTING

None

### FIELD OF THE INVENTION

The invention relates to the area of obtaining and using a nanostructured optically transparent compound based on the polymer composition including the polyurethane derivatives and the special modifiers that can be used for encapsulation, lamination and protection in radioelectronic and various optical devices including PV modules.

The present invention relates also to the photovoltaic conversion of light and specifically to the use of flexible optically transparent nano structure polymer coating and encapsulation materials to replace glass for PV modules, including metal doped coatings and coatings with antistatic additives, that is applied directly onto the surface of photovoltaic cells to protect the semiconductor materials, enhance the overall efficiency of the photovoltaic device, increase the resistance to degradation by UV, ionizing radiation, and humidity and have lower cost, reduced weight, and improved mechanical strength of PV modules.

### BACKGROUND

Increased photovoltaic cell efficiency and use of lower cost materials are important factors in reducing the cost of solar energy. In addition to the photoelectric conversion efficiency of the specific cells, encapsulation and protective layer material characteristics are important in determining overall photovoltaic device performance that include the resistance to degradation by UV and ionizing radiation, humidity, provide the lower cost, reduced weight, and improved mechanical strength of PV modules.

Photovoltaic conversion efficiencies can be increased by:
Optimizing the conversion efficiency over an extended spectral range including UV portions of the spectrum,
Decrease the level of the reflection from the protective layer surfaces,
Alter protective coating surface morphology so as to increase the re-capture of photons initially reflected from the surface and direct more light to the active cell as well as provide concentration effect to change the way of the light and repeated reflection from the internal volume of the coated layer.

Increasing sensitivity to the shorter wavelength portions spectrum can help increase overall efficiency.

Ensuring a high sensitivity under the wide wavelength of the spectrum including the shorter wavelength portions spectrum would be important for other types of the photovoltaic based on the flexible solar cell, for examples CIGS and other.

This objective can be achieved by several means, including a reduction in the depth of the electron—hole transition, passivation of near-surface area in which a basic absorption of a shorter wavelength part of the spectrum takes place, using high transparency coverings, etc. For the infra-red area designs that promote the repeated reflection from a back surface are useful.

To realize the goal increasing the efficiency of the reliability of the PV modules and other optical devices it is also necessary to pay attention to the methods and materials for hermetic sealing of photovoltaic cells and modules. The way in which photovoltaic active surfaces are sealed and protected can have a significant effect on their performance. It is important also from the point of view protection from the humidity. This application is imoirtant for the DSSC solar cells and organic solar cell as well,

The most common material that us used for protecting the photovoltaic cell is a sheet semi-tempered glass with a thickness of 3-4 mm. Between the glass and surface of the photovoltaic cell the adhesive polymer material is placed, for example ethylene-vinyl-acetate (EVA). Such glass lamination has several disadvantages which include as following:
Glass is relatively:
   heavy
   brittle
   reflective: light reflected from the glass surfaces (both exterior and interior) does not reach the solar cell underneath
PV modules that use glass comprise a multi-layered structure that is more expensive and complicated to manufacture as compared to the new PV modules design according presented invention.

The additional disadvantages of the conventional glass as a protective covering for photovoltaic modules are because the glass it is not efficient in transmitting light in the UV portion of the spectrum. In fact, the glass commonly used for PV module covering absorbs substantially in the UV portion of the spectrum. Glass tends to block ultraviolet light, thus reducing the energy that can be obtained from this part of the spectrum.

As a result, PV modules laminated with glass have a limited efficiency and is problematic for using for the PV modules.

Using conventional polymer and glass-like inorganic encapsulation and protective layers, current mono-crystalline and multi-crystalline silicon based photovoltaic systems have module conversion efficiencies in the range of 13%-15%. For a typical commercial mono-crystalline photovoltaic module, such efficiency corresponds to a current density of approximately 34 mA/cm².

Higher efficiencies (more than 20%) have been reported for mono crystalline and multi crystalline solar cells for terrestrial use, but only for the small sized laboratory samples (approximately 1 cm²). Such conversion efficiencies have also been achieved for larger cell sizes based on more expensive technology, such as that used for space-based applications. In this case the special high expensive materials and technologies are used.

Yet another disadvantage of glass coverings complexity of manufacturing cells modules lamination with glass. The process of lamination of photovoltaic modules includes using of several expensive materials. The sealing of glass to the cell is carried out under vacuum in a laminating chamber at temperatures on the order of 150° C.

Thus the disadvantages of using glass as a covering for photovoltaic cells, as compared to the nano structured polymer coating described in the present invention, include: the relatively high cost and weight of glass complexity of assembling the glass-photovoltaic cell unit, the reflectivity of glass and the absorption of energetic photons in the UV portion of the spectrum. Glass can not be used for flexible PV modules.

Some solar cell modules systems use the concentrators for increasing the efficiency. Concentrating photovoltaic systems (CPV) use a large area of lenses or mirrors with the goal focusing the sunlight on a small area of photovoltaic cells. Concentrating systems use also the single or dual-axis tracking the sun's position for improving the PV modules performance. The primary attraction of CPV systems is reducing the usage of semiconducting material which is expensive and currently in short supply. Additionally, increasing the concentration ratio improves the performance of general photovoltaic materials.

However, these concentrating system structures are expensive and require the systems for cleaning and tracking the sun's position. A further disadvantage of optical concentrators is the fact that they can increase the size and weight of the PV module system, costs of focusing, tracking and cooling equipment.

The polymer materials that are currently used for protect the semiconductor materials of the different optical elements and for covering the front face area of photovoltaic modules do not have the robust physical and mechanical properties exhibited by the polymer materials developed according the presented invention.

Currently available polymers from the market do not provide any increasing in the efficiency of the photovoltaic devices on which they are used while polymer materials presented according current invention provide increase the efficiency of PV module. The currently available polymers which are used for encapsulation the PV modules do not combine the high level of the adhesive, high transparency, concentration of incoming light, resistance to degradation by UV and the resistance to degradation by ionizing radiation, resistance to humidity, and improving the mechanical strength.

The nano structured transparent polymer material for encapsulation the PV modules and other optical devices that is presented in the current invention combine the properties described above.

An objective of the present invention is to achieve based on the polyurethane derivatives with the hardener and the modifier the transparent polymer materials with high physical and optical properties, high resistance to degradation by UV and ionizing radiation, reduced weight, and improved mechanical strength.

These transparent polymer materials are achieved based on the for polymers or oligomers with the additives of the hardening agent, antistatic additives, metal dopants, and the additives of the modifiers which have the active chemical affinity to the original components of a composition.

These transparent polymer materials can provide increasing efficiency for modules comprised of different types of solar cells including, but not limited to: monocrystalline silicon, multicrystalline silicon, amorphous and nono-crystalline silicon and for non-silicon systems such as CIGS and others flexible systems like DSSC and organic solar cell.

According invention that is presented here the requested properties of the nano structured polymer materials for encapsulation the PV and other optical devices are achieved by modifying the composition based on polyurethane compounds using the modifiers from the class of low molecular weight esters.

Along with the fact that the transparent polymer that is coordinated with invention that is presented here can replace glass this transparent polymer could be used also as the adhesive layer between the solar cell surface and the glass. In this case transparent polymer according presented invention will replace polymer like EVA. The role of the nanostructuted transparent polymer will be more effective then EVA due to the concentration of light; in facilitation of the technology, and protection from moisture due to the high adhesive properties.

The transparent polymer material according the presented invention can be also used for coating the outer side of the glass with the goal to protect glass from UV influence and from the destruction.

### BRIEF DESCRIPTION OF THE INVENTION

The invention presented here involves increasing the protection and the operating properties of the optical elements in semi conductive industry and well as involves increasing the efficiency and the reliability of photovoltaic cells or solar cell modules based on-mono-crystalline, multi-crystalline, amorphous, and nano-crystalline silicon based systems and for non-silicon systems such as CIGS (copper indium gallium selenide) as well as other solar cell types like DSSC and organic.

In the presented invention this goal is achieved by using flexible nanostructure optically transparent cover layers for protecting the surface of the photovoltaic modules and other optical devises. The specially formulated polymer is based on epoxy urethanes oligomer or polyurethane olygomer into which the hardening agent, anti-static additives, conducting metal additives, hardener and modifier (additive, modifying the properties of the polymer) have been incorporated with wherein the surface of flexible optically transparent cover has a flat coat surface morphology or relief/crinkle coat surface morphology.

As the modifier the components from the class of low molecular weight esters with the general formula that is presented below are used:

R—C(O)—OR′,

where R could be for example ═CH₃, C₂H₅;

and R′ could be for example ═CH₃, C₂H₅, C₄H₉, C₅H₁₁.

The polymer coating materials with modifier and method of hermetic sealing according the invention presented here has several advantages in that it improves the following aspects of PV module characteristics and performance as compared with polymer without modifier:
Increasing the efficiency of the utilization of shorter wavelength range of the spectrum, including UV due to the high transparency of the polymeric coating and effect of concentration and [symbol] [symbol] [symbol] [symbol] .
Increasing the short circuit currents for solar cells for example based on the silicon
Increasing the open circuit voltage for solar cell based on non silicon materials, for example CIGS.
Increasing the adhesion to any materials, including solar cells based on silicon, CIGS, polymer materials, ets.
High mechanical strength and possibility provide the high level flexibility for optical devices including PV modules.
The polymer coating of the present invention is more resistant to degradation by UV and ionizing radiation (so-called photon degradation) than previously described coating polymers.
Increasing the value of the index of refraction as compared to glass provides a reduction in reflection (clarifying effect).
Capability to form surface relief of various types, including a surface consisting of set of micro lenses (concentrating properties).
Capability to be formed with a relief/crinkle coat surface morphology and to thus change the trajectory of incident photons.
Stability when exposed to high and low temperatures and thermal-cycling, mechanical impact, and high relative humidity
Reduction in weight and cost compared with PV module laminated by glass.

The hardening agent, anti-static additives, conducting metal additives and modifier have been incorporated to the forpotumer of oligomer-based polymer materials used in the present invention, to improve weathering and environmental properties and impart higher conversion efficiencies while retaining high optical transparency.

Tests on solar cells based on improvements of the present invention, comparing them to solar cells and PV modules without coating and solar cells and PV modules laminated with glass were carried under a variety of natural and artificial lighting conditions. These tests demonstrated that the photovoltaic cells and modules of the present invention offer substantially improved performance under wide operating range of light.

The present invention allows to increase efficiency and reliability including increasing the water and UV proof of photovoltaic devices based on mono-crystalline, multi-crystalline, amorphous silicon and non-silicon based solar cell modules like CIGS, DSSC, and organic solar cells.

Under standard conditions of illumination and temperature, a solar cell based on monocrystalline or multicrystalline silicon and coated with the polymer materials according of the present invention showed up to 14% increase in current density over a monocrystalline or multicrystalline silicon solar cell without any coating. It means that as compared with the PV module that is laminated with glass the increasing of the efficiency for the PV module that is incapsulated with nanostructure transparent polymer will be even higher.

Under standard conditions of the illumination and the temperature a thin PV modules based on CIGS solar cells and coated with the polymer materials according of the present invention showed up to 10% increasing the open circuit voltage as compared with thin PV CIGS module without any coating. This effect is new and not obvious.

Under low level of illumination (450 Lx) for example under the overcast weather, the torrential rain the level of the increasing the open circuit voltage of the PV CIGS module coated with the polymer materials according presented invention showed up to 75% increasing the open circuit voltage as compared with thin PV CIGS module without any coating. It means that using the transparent polymer material presented in the current invention for encapsulation/coating PV modules it is possible effective using the PV modules even under low level of illumination for example, overcast weather, torrential rain or in door.

The effect of increasing the efficiency of solar cells when using the nano structured transparent polymer encapsulation that is proposed in this invention is manifested in a wide range of lighting conditions. It is important that this effect appears even stronger at a low-light appears. This significantly expands the areas and conditions using the PV modules manufactured according with presented invention.

Key elements of this new technology includes nano structured transparent polymers that are flexible, durable has a high level of adhesion for various materials, provide a high level of the waterproof and UV protection, and contains in the structure ordered the nano structured clusters with the sized from 20 nanometer to 100 nanometer and micro-domains with sizes from 15 to 120 microns. Such composition of the nano structured clusters and micro-domains, located in a certain order in the volume of the polymer play the role of micro lenses, which provide the concentration of the light. At the micro-domains fields occurs enhancement of optical radiation. As results the PV modules efficiency increased.

The structure of the nano-and micro-clusters in the bulk polymer is formed due to the introduction of the modifier, which has an active chemical affinity to the original components of the polymer composition, and due to the nano technology encapsulating the surface of PV modules with the nano-structured polymer film.

Using a unique polymer protective layer coated materials which are coated in the surface of a photovoltaic converter or solar cell as well as improved photovoltaic modules designs, photovoltaic modules of the present invention achieve conversion efficiencies of 20% (relative), or more higher, as compared with PV modules laminated with glass. The photovoltaic modules of the present invention can achieve current densities of 40 mA/cm², or more.

The unique polymer protective coated layer can be used in the form of flat smooth surface or with a “crinkle coat” surface. In the case of the “crinkle coat” surface an additional increase the efficiency and current density is achieved.

As a result, the photovoltaic cells and modules of the present invention are substantially less expensive than current commercial photovoltaic systems on a cost per watt basis. Also, the polymer materials which are used according this invention are less expansive as compared with the glass that is currently used to cover the front-face area of photovoltaic modules. The polymer material which are used according this invention have also a higher relative lengthening and resistance to breakage as compare with other polymer material that are used for the similar application, for example, for PV modules coating/encapsulation.

The areas and conditions using the optical devices and PV modules significantly expanded when are manufactured according with the presented invention. A flexible optically transparent polymer materials according with presented invention could used for lamination, encapsulation or coating wherein the flexible optically transparent cover is generated as a result of dispersion of an initial mixture of organic material or as a result of flowing the organic material on the front-face surface of the optical device including the PV modules, optical devices with a complex configuration, concentrated systems for PV modules including plastic lenses, for forming coating layers on the fresnel lens's, in microreplication, and as an interlayer between glass and possibly other polymers to create laminated bullet-proof windows

### DESCRIPTION OF THE DRAWINGS

FIG. 1 represents the make-up of a solar cell module which includes: substrate with insulating surface 101, adhesive layer 102, photovoltaic converters 103, transparent conductive oxide layer (for example ITO: Indium Tin-Oxide) 104, highly transparent flexible protective cover layer 105 made from polymeric material. A adhesive layer for back sheet (102) the polymer materials developed in the presented invention could be used.

FIG. 2 depicts the open circuit voltage of the PV modules samples based on CIGS, when tested in various weather (field) conditions. In the FIG. 1 the number of samples shows the type of PV. The sample No. 1 is the initial samples, without polymer coating. The samples No. 2 and 3 are the samples with polymer coating. The letters on the axis of abscissa correspond to different conditions under which the test of the PV modules has been conducted:

A. Overcast weather, torrential rain, λₘₐₓ=380 . . . 450 nm, E=450 Lx;

B Clouds, λₘₐₓ=380 . . . 450 nm, Illumination=1200 Lx

C. Clouds, λₘₐₓ=400 . . . 550 nm, Illumination=4000 Lx

D. Bright sun, λₘₐₓ=550 . . . 650 nm, Illumination=40000 Lx

FIG. 3 shows the AFM image of the topography (a) and the RFM image of the surface distribution of the nanostructures (b) for optically transparent polymer composition that is formed on the surface of a silicon single crystal

FIG. 4 shows the micrograph of the silicon substrate that is encapsulated with nanostructured transparent polymer.

FIG. 5 shows transmittance of semi-hardened glass with thickness of 1.7 mm as a function of wavelength

FIG. 6 shows transmittance as a function of wavelength for the polymer layer based on forpolymer and the mixture of the [symbol] - [symbol] [symbol] [symbol] [symbol] [symbol] [symbol] as a hardener

FIG. 7 shows transmittance as a function of wavelength for the polymer layer in the composition according invention presented here.

FIG. 8 shows the photo of polymer film according the presented invention when this photo was received by optic microscope PRIMO STAR, Carl Zeiss. Magnification—2000; the scale is presented on the photo. The typical dimensions of micro-clusters of 10 to 150 microns.

FIG. 9 depicts characteristic of the solar cell module before capsulation with transparent polymer (901) and after capsulation with transparent polymer (902). The halogen lamp with the UV filter was the radiation source. The power of the halogen lamp was 1000 W.

FIG. 10 depicts characteristic of the solar cell module before lamination with glass (1001 1) and after lamination with glass (1002-2). The halogen lamp with the UV filter was the radiation source. The power of the halogen lamp was 1000 W.

FIG. 11 depicts characteristic of the solar cell module before capsulation with transparent polymer (1101) and after capsulation with transparent polymer (1102). The halogen lamp without the UV filter was the radiation source. The power of the halogen lamp was 2000 W.

FIG. 12 depicts characteristic of the solar cell module before lamination with glass (1201) and after lamination with glass (1202). The halogen lamp without the UV filter was the radiation source. The power of the halogen lamp was 2000 W.

FIG. 13 depicts characteristic open circuit voltage under different illumination for PV modules based on CIGS. Sample 4 is without encapsulation; samples M-24 and 5 with eTcapsulation.

FIG. 14 shows the dynamics of the absorption of the water in polymer film.

FIG. 15 shows the experimental values of small-angle X-ray scattering (in electronic units) for samples nanostructured optically transparent materials with different ratio of initial components.

FIG. 16. shows the values of small-angle X-ray scattering (reduced to “point” collimation) for the same samples which are presented on the FIG. 15.

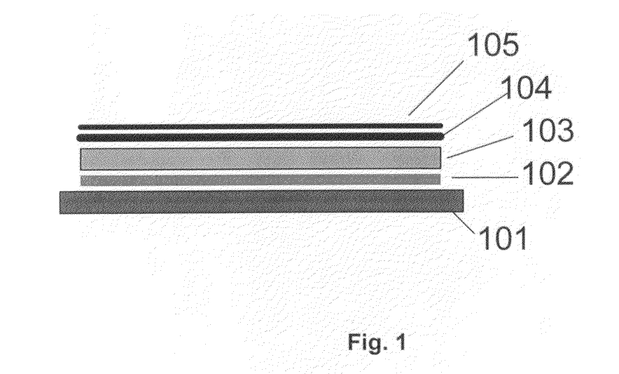

### DETAILED DESCRIPTION OF THE INVENTION

The invention relates to the area of obtaining and using an optically transparent compound based on the polyurethane derivatives and the special modifiers that can be used for encapsulation, lamination and protection in radioelectronic and various optical devices including PV modules.

The present invention relates to the photovoltaic conversion of light and specifically to the use of flexible optically transparent polymer coating and encapsulation materials to replace glass for PV modules, including metal doped coatings and coatings with antistatic additives, applied directly onto the surface of photovoltaic cells to protect the semiconductor materials, enhance the overall efficiency of the photovoltaic device, increase the resistance to degradation by UV and ionizing radiation, and have lower cost, reduced weight, and improved mechanical strength of PV modules.

This goal is achieved by using nano structured flexible optically transparent cover layers for protecting the surface of the photovoltaic cells and other optical devised. The specially formulated polymer is based on epoxy urethanes oligomer or polyurethane olygomer into which the hardening agent, anti-static additives, conducting metal additives, hardener and modifier (additive, modifying the properties of the polymer) have been incorporated with wherein the surface of flexible nano structured optically transparent cover has a flat coat surface morphology or relief/crinkle coat surface morphology.

These problems are solved by modifying the composition of the polymer in the process of obtaining when the modifier is from the class of low molecular weight esters with the general formula that is presented below are used:

R—C(O)—OR′,

where R could be for example ═CH₃, C₂H₅;

and R′ could be for example ═CH₃, C₂H₅, C₄H₉, C₅H₁₁.

These modifiers have active chemical affinity to the initial components of the composite. With the introduction of the modifiers which are from the class of compounds of low molecular weight complex esters the formation the nano structure is occurred. During the process of polymerization and curing in the bulk of a transparent polymer material the forming the nano-ordered structures or nano clusters with the sizes from 20 nanometer to 100 nanometer and micro-ordered structures or micro clusters with sizes ranging from 15 to 150 micron is occurred.

The ordered micro clusters which are obtained play role of microlenses, which concentrate light. At the nano and micro regions the wave amplification of optical radiation is occurred. As a result, the efficiency of PV modules increases (Example 1); the transparency in the area with a low wavelength increases; in particular in the UV region (Example 8); the mechanical and adhesive properties of the polymer coating improves (Examples 3, 4 and 5).

Modifier is bonded by the intermolecular hydrogen bonds with a components of the basis of the compound (forpolymer or oligomer) and with the hardeners. This explains the role of the modifier. Thus, different functional groups, which are in the structure of the polymer, as a result of the intermolecular interactions form clusters, domains of different sizes, and configurations. Such a hierarchy of structures contributes to structural heterogeneity, which provides increasing the efficiency of energy conversion of optical radiation into electrical energy due to the effect of the concentration of optical radiation, and the wave amplification of the optical radiation. Structure of the clusters and the domains depends on the composition of the materials and also on the parameters of technological process of transparent polymer film formation.

When obtaining the nano structured transparent polymer with the properties described in invention presented here the following materials and processes are used:

Initial materials (forpolymer, oligomer) are synthesized on the basis the different composition of the poliglicoladipinats or polyethyleneglycoladipinat for example the which have different molecular weight, and on the basis of the aliphatic diisocyanates for example hexamethylendiisocyanate with different ratio between them

Then conduct the mixture of forpolymer, hardener and modifier. As the hardener the bi- and trifunctional hydroxyl compounds in different combination are used. The modifier quantity could be 5 . . . 60%. As a modifier a chemicals from the class of the low-grade esters of general formula that is presented above are used.

The flexible optically transparent cover could be generated on the light-facing area of the photovoltaic converters in one of two ways:
Flowing the organic material onto the front-face surface of the photovoltaic cell, or
Dispersion of initial mixture of organic material on the front-face surface of the photovoltaic cell

Then deposited organic materials kept at a temperature of 65-80° C. to complete the curing or before full hardening.

Specific composite of the initial materials for transparent polymer is depended on the type of solar cell and the operating conditions PV modules that are planned.

The goal of this invention is also to provide optical devices and solar cell modules of high efficiency and mechanical durability for while simultaneously decreasing the cost of the module. These objectives of this invention are achieved through the use of new polymer materials and PV module design which is implemented based on this materials.

Transparent polymer materials and coating technologies that provide requested properties and increase the efficiency of PV modules can be used to improve the conversion efficiencies of many types of photovoltaic devices. Examples include solar cells based on mono-crystalline silicon, multi-crystalline silicon, amorphous silicon, nano-cryctalline silicon as well as solar cells based on non-silicon systems such as CIGS (copper indium gallium selenide) etc.

While transparent polymer materials according presented invention provide increasing efficiency for various type of solar cells this transparent polymer materials provide also not obvious effect of apparent additional manifested. In this case not only short circuit current (A), but also the open circuit voltage, (V) increased when laminate/encapsulate solar cell with transparent polymer materials according invention presented here. More detailed information presented in examples below.

Under standard conditions, the photovoltaic cell of the present invention showed up to 13% increase in current density and up 3% increase in open circuit voltage (V) over initial PV modules no capsulated with transparent polymer. As results the efficiency also increases. These results were achieved for solar cell based on mono crystalline and multi crystalline silicon solar cell. In means that when compare the solar cell with transparent capsulated polymer and solar cell laminated with a glass effect of the increasing efficiency will be even higher. Results of the test that are described in the example confirm this effect. Some examples of the solar cells have a size 155×155 mm

Under standard conditions the CIGS PV modules capsulated with transparent polymer of the present invention showed up to 14% (relative) increase in the open circuit voltage (V) over initial PV modules no capsulated with transparent polymer. Of special interest was the performance of the PV modules based in the CIGS under various nature conditions including bright sun, clouds and overcast weather, torrential rain.

The following not obvious effect of apparent additional manifested from the point if view the efficiency solar cell when use the transparent polymer according the invention presented here. When compare efficiency the initial solar cell without polymer and solar cell with polymer this effect depended on the power of light. As shown in Example 2 under bright sun the open circuit voltage (V) PV modules based on CIGS that is encapsulated with transparent polymer increases up to 10-14% (relative) as competed with the initial PV modules based on CIGS that is no encapsulated with nanostructure transparent polymer. At the same time under overcast weather, torrential rain the open circuit voltage (V) PV modules based on CIGS that is encapsulated with transparent polymer increases up to 60% as competed with PV modules based on CIGS that is no encapsulated with nano structured transparent polymer. The short circuit current (A) can increase on 12.7% (relative).

Another element of the present invention is the use of substrates that are made from metal covered by an insulating layer. Aluminum oxide deposited onto an aluminum metal sheet or foil is an example of such a substrate

Another aspect of the invention is use of the transparent film of a conductive oxide metal which is located between the flexible optically transparent cover and front-face surface of the photovoltaic cell. Indium tin oxide (ITO) coated onto polyethylene is and example of such as transparent cover.

Another aspect are the metal additives, that allow use nanostructure transparent polymer for encapsulation the PV modules without additional electronic contacts.

### Examples

The Examples described below are provided for illustration purposes only and are not intended to limit the scope of the invention.

Artificial lighting for comparative testing was provided by halogen lamps as the radiation source. The test was conducted with and without UV filter. The various halogen lams were used: with power 1000 W and 2000 W; with illumination 45000 Lx and 40000 Lx. The PV modules were placed in the center of this light field

### Example 1

Four solar cell based on multi crystalline silicon and four solar cell based on monocrystalline silicon have been encapsulated with polymer materials with the modifier according the presented invention. Size of solar cell is 115 mm×115 mm.

Aluminum sheeting that was anodized for forming the insulating layer was used as the substrate onto which the back of the photovoltaic converter was affixed.

The flexible optically transparent cover on the front-face surface of the photovoltaic cell, Results from tests on the eight solar cells according to the present invention are shown in Table 1 below. In the Table 1 parameters of the open circuit voltage, current, and efficiency of the solar cells before and after encapsulation with nano structured transparent polymer according presented invention are presented.

The size of the solar cells is 235, 56 cm². Halogen lamp with UV filter was the radiation source. Power 1000 W, Illumination: 45000 Lx

Solar cells No. 1, 2, 3 and 6 were based on multicrystalline silicon. Solar cells No 4, 5, 7 and 8 were based on monocrystalline silicon.

TABLE 1
Performance data for solar cells before, and after encapsulation
in accordance with the present invention.

| | Before | | After | | Efficiency | |
|---|---|---|---|---|---|---|
| | encapsulation | | encapsulation | | under load, % | |
| No | Open circuit | Current, A, | Open circuit | Current, A, | Before | After |
| samples | voltage, V | under load | voltage, V | under load | encapsulation | encapsulation |
| 1 | 0.6 | 6.05 | 0.620 | 6.7 | 12 | 13.75 |
| 2 | 0.61 | 5.95 | 0.620 | 6.55 | 12 | 13.44 |
| 3 | 0.61 | 5.8 | 0.625 | 6.55 | 11.7 | 13.56 |
| 4 | 0.605 | 5.9 | 0.615 | 6.65 | 11.82 | 13.54 |
| 5 | 0.61 | 5.9 | 0.610 | 6.62 | 11.9 | 13.37 |
| 6 | 0.615 | 5.9 | 0.615 | 6.65 | 12.0 | 13.54 |
| 7 | 0.605 | 5.95 | 0.610 | 6.60 | 11.92 | 13.33 |
| 8 | 0.610 | 6.05 | 0.615 | 6.75 | 12.32 | 13.75 |

Halogen lamp with UV filter was the radiation source. Power 1000 W, Illumination: 45000 Lx

In the Table 2 results from tests on the eight solar cells according to the present invention without UV filter are shown in Table 2 below. Solar cell size—235, 56 cm². Halogen lamp without UV filter was the radiation source. Power 2000 W, Illumination: 40000 Lx

TABLE 2
Performance data for solar cells before, and after encapsulation
in accordance with the present invention.

| | Before encapsulation | | After encapsulation | |
|---|---|---|---|---|
| No | Open circuit | Current, A, | Open circuit | Current, A, |
| samples | voltage, V | under load | voltage, V | under load |
| 1 | 0.6 | 6.25 | 0.62 | 7.0 |
| 2 | 0.61 | 6.15 | 0.62 | 6.75 |
| 3 | 0.61 | 6.0 | 0.62 | 6.75 |
| 4 | 0.605 | 6.1 | 0.615 | 6.85 |
| 5 | 0.61 | 6.1 | 0.605 | 6.8 |
| 6 | 0.615 | 6.1 | 0.615 | 6.85 |
| 7 | 0.605 | 6.15 | 0.605 | 6.7 |
| 8 | 0.610 | 6.25 | 0.615 | 6.85 |

Halogen lamp without UV filter was the radiation source. Power 2000 W, Illumination: 40000 Lx

For solar cell based on mono crystalline silicon increasing the current (A) under load when encapsulating the PV modules nano structured transparent polymer could be 12.7% (relative) and increasing the open circuit voltage (V) could be 1.5% (relative). For the solar cell based on multicrystalline silicon the increasing the current (A) under load could be 12.9% (relative) and increasing the open circuit voltage (V) could be 3% (relative).

Short circuit current for solar cell without encapsulation could be 7.1 A. After encapsulation according presented invention the short circuit current for solar cell increased and could be 8 A. Increasing of the Short circuit current after encapsulation was 12.6% (relative).

The data which are presented in the Tables 1 and 2 demonstrate the increasing the current density and conversion efficiency of modules which are made according to the invention presented here.

### Example 2

Two PV modules based of CIGS were encapsulated with polymer materials with the modifier according presented invention. Below in Table 3 parameters of PV modules based on VIGS solar cells before and after encapsulation with polymer materials according presented invention are presented. Size of PV modules is 5×8 cm². Halogen lamp was with the UV filet

TABLE 3
Parameters of PV modules based on VIGS solar
cells before and after encapsulation with polymer
materials according presented invention.

| | Before encapsulation | | After encapsulation | |
|---|---|---|---|---|
| No | Short circuit | Open circuit | Short circuit | Open circuit |
| samples | current, A | voltage, V | current, A | voltage, V |
| 5 (2) | 35.9 | 8.2 | 35.6 | 9.06 |
| M-24 (3) | 25.6 | 8.64 | 25.0 | 9.5 |
| 4 (1) | 39 | 8.3 | | |

Halogen lamp with UV filter was the radiation source. Power was 500 W, illumination was 40000 Lx.

Below in Table 4 parameters of the PV modules based on CIGS solar cells under different conditional of the light are presented.

Under bright sun and the high level of illumination (40000 Lx) the level of increasing the open circuit voltage of the PV CIGS module encapsulated with the polymer materials according presented invention showed up to 9-13% (relative) as compared with thin PV CIGS module without any coating.

Under clouds and the level of illumination 4000 Lx the level of increasing the open circuit voltage of the PV CIGS module encapsulated with the polymer materials according presented invention showed up to 38-45% (relative as compared with thin PV CIGS module without any coating.

Under clouds and the level of illumination 1200 Lx and under even less level of illumination like 450 Lx for example under overcast weather, and torrential rain the level of the increasing the open circuit voltage of the PV CIGS module encapsulated with the polymer materials according presented invention showed up to 60-75% (relative) as compared with thin PV CIGS module without encapsulation.

At the same time for the PV module based on CIGS without encapsulation (sample 3) when illumination decreases from 40000 Lx to 450 Lx the open circuit voltage, V decreases from 8.3.V to 2.6 V than means 67% (relative).

For the PV modules based on CIGS and encapsulated with transparent polymer according presented invention (sample 2) when illumination decreases from 40000 Lx to 450 Lx the open circuit voltage, V decreases from 9.5.V to 4.53 V than means 52% (relative) or (samples 1) from 9.05 V to 4.18 V that means 53% (relative).

Results of the test which are presented here confirm that the using the transparent polymer material presented in current invention for encapsulation/coating PV modules it is possible the effective using the PV modules even under low level of illumination for example, overcast weather, torrential rain or in door.

The effect of increasing the efficiency of solar cells when using polymer encapsulation (coating) proposed in this invention is manifested in a wide range of lighting conditions. It is promising that this effect appears even stronger at a low-light. This significantly expands the areas and conditions using the PV modules manufactured according with presented invention.

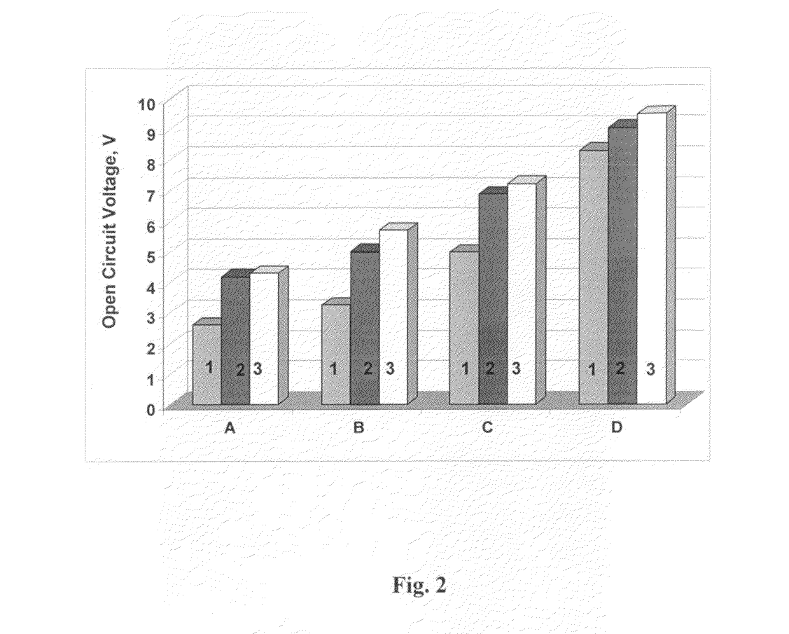

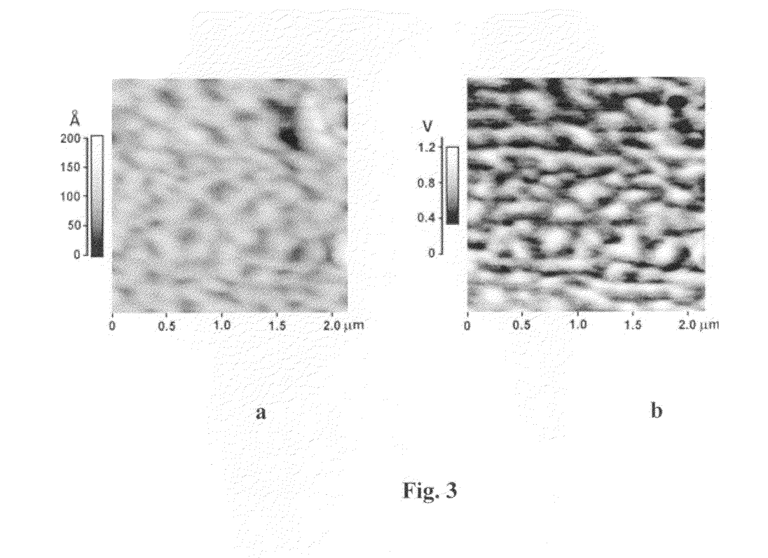

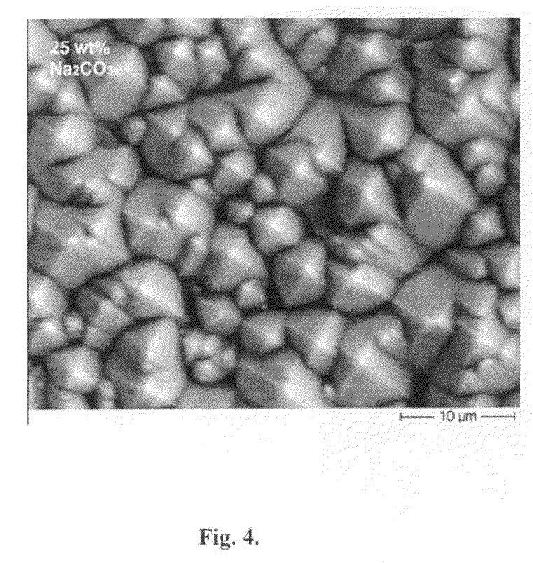

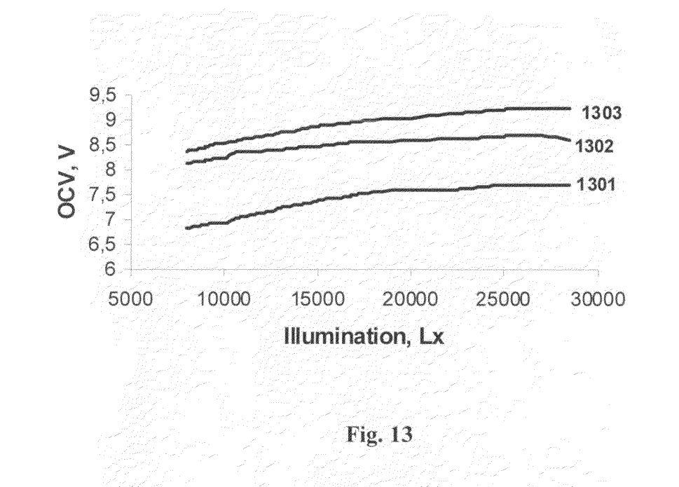

Results that are described in Example 2 are presented in FIG. 2 and FIG. 13.

TABLE 4
Parameters of the PV modules based on CIGS solar cells with and without transparent polymer
encapsulation according presented invention under different conditional of the light.

| | Number of PV modules | | | | | |
|---|---|---|---|---|---|---|
| | | | 5 (2) With | | M-24 (3) With | |
| | 4 (1) Initial, without | | polymer encapsulation | | polymer encapsulation | |
| | polymer encapsulation | | | % over initial | | % over initial |
| | Open Circuit | | Open Circuit | cell without | Open Circuit | cell without |
| Conditions of test | Voltage, V | • | Voltage, V | encapsulation | Voltage, V | encapsulation |
| Illumination: 450 | 2.60 | | 4.18 | 160% | 4.53 | 174% |
| Lx,. | | | | | | |
| λₘₐₓ = 380 . . . 450 nm | | | | | | |
| Overcast weather, | | | | | | |
| torrential rain | | | | | | |
| Illumination: 1200 | 3.25 | | 5.00 | 153% | 5.70 | 175% |
| Lx | | | | | | |
| λₘₐₓ = 380 . . . 450 nm | | | | | | |
| Clouds | | | | | | |
| Illumination: 4000 | 4.98 | | 6.88 | 138% | 7.22 | 145% |
| Lx | | | | | | |
| λₘₐₓ = 400 . . . 550 nm | | | | | | |
| Clouds | | | | | | |
| Illumination: 40000 | 8.3 | | 9.051 | 109% | 9.50 | 114% |
| Lx | | | | | | |
| λₘₐₓ = 550 . . . 650 nm | | | | | | |
| Bright sun | | | | | | |

### Example 3

The preparing and coating of the polymer film on the light-facing surfaces of the photovoltaic cells was carried out in the following steps:

1. Preliminary preparing of the forpolymer. A mixture of the polyethyleneglycoladipinat and the hexamethylendiisocyanate was used.
The mass ratio between the polyethyleneglycoladipinat and hexamethylendiisocyanate was 2:5.4-6.6
The temperature during mixing was 60-80° C.
The duration of mixing was 50 minutes

Forpolymer can be stored in airtight container in a dry nitrogen atmospher during 5 months

2. Preparation of the hardener. As a hardener, a mixture of trimethylpropane and butenediol was used. The mass ratio between trimethylpropane and butenediol was 9.5:0.5.

3. Preparing the mixture of the oligomer, hardener and modifier. The mass ratio between oligomer and hardened was 100:4.0. The percent of the modifier was 20%. The mixture of the oligomer, hardened and modifier was mixed during 10-20 minutes under vacuum to remove the bubbles.

The flexible optically transparent cover is generated as a result of flowing or dispersion the mixture of transparent liquid organic material onto the front face surface of the optical device, for example the photovoltaic cell module. Then deposited organic materials kept at a temperature of 65-80° C. to complete the curing ((before full hardening).

Like the example 3 the other compounds, composition, the conditions for which are presented in the Table 5.

TABLE 5
Composition of the polymer and parameters of the process.

| | Samples | | | |
|---|---|---|---|---|
| | | | | 4 |
| Components, temperature and time | | | | Without |
| of the compound fabrication | 1 | 2 | 3 | modifier |
| Polyethyleneglycoladipinat, M | 1 | 1 | 1 | 1 |
| Hexamethylendiisocyanate, M | 1.8 | 2.0 | 2.2 | 2.0 |
| Temperature of the | 65 | 70 | 75 | 70 |
| forpolymer synthesis, ° C. | | | | |
| Duration of the forpolymer | 35 | 30 | 25 | 55 |
| synthesis, [symbol] | | | | |
| Quantity of the hardener on the | 7 | 8 | 9 | 9 |
| 100 parts by weight of the forpolymer. | | | | |
| Temperature of the mixing, ° C. | 55 | 60 | 65 | 60 |
| Duration of the mixing, min | 20 | 15 | 10 | 15 |
| Modifier, molar units. | 15 | 20 | 25 | — |
| Temperature of the | 60 | 70 | 80 | 60 |
| compound curing, ° C. | | | | |

The polymer films that were obtained according presented invention were tested. In the Table 6 below the results of the following testing are presented: mechanical properties, optical properties, properties, water absorption.

Testing of the mechanical properties of transparent polymer film which was obtained according presented invention was conducted under following conditions:

The mechanical tests were conducted at room temperature. The breaking machine type RM-30 machine was used. Force was applied at a rate equivalent to 100 mm/min. Measurement error was 3% to 5%.

Parameters tested for mechanical properties:
Relative lengthening
Resistance to breakage/Tensile strength

Polymer film dimensions for test mechanical properties were as following:
thickness of the film: 1 . . . 2 mm
film sample size: 5 mm×50 mm

Test conditional for determination of water absorption by polymer films that were obtained according presented invention

Polymer film dimension for determination of water absorption were as following
thickness of the film: 5 mm
diameter of the film: 7 mm

Description of the test for determination of water absorption:

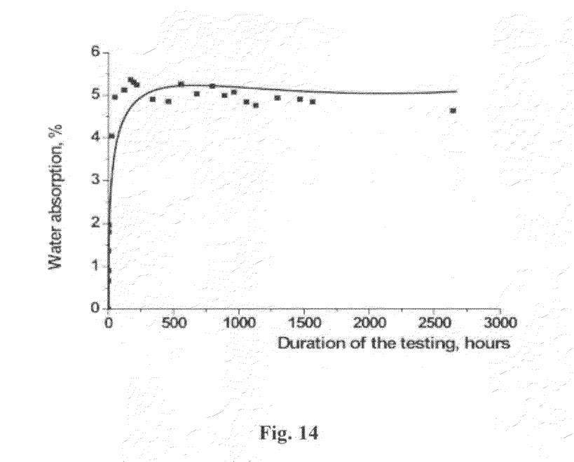

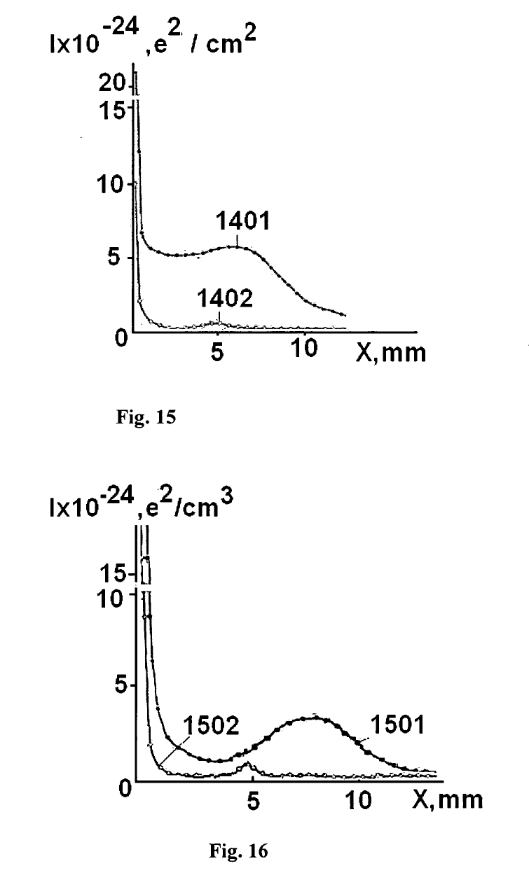

Water absorption was measured by evaluation the relative change in weight of the polymer film samples after immersion in water. Measurement error did not exceed 5%. Results of the test are presented in the Table 7 and in FIG. 14.

TABLE 6
Properties of transparent polymer films without modifier and with modifier (samples 1, 2, and 3)

| | | | | | | The transmission | The transmission |
|---|---|---|---|---|---|---|---|
| | | | | | | of light in the | of light in the |
| | Index of | Relative | Tensile | Water | | visible region, | UV region, |
| | Refraction | lengthening, | strength | absorption, | External | the thickness of | the film |
| Samples | Value | % | kg/cm² | % | view | the film 2 mm | thickness 2 mm |
| Without | 1.49 | 100 | 19 | 5 | Transparent colorless, | 92 | 82 |
| modifier | | | | | | | |
| 1 | 1.50 | 200 | 29 | 5 | Transparent, colorless | 94 | 88 |
| 2 | 1.51 | 300 | 30 | 4 | Transparent, colorless | 95 | 90 |
| 3 | 1.49 | 350 | 32 | 5 | Transparent, colorless | 96 | 92 |

The data presented in the Table 6 show that the introduction of the modifier leads to further improve the physical and mechanical properties compared with materials that do not have modifier Light transmission increases in both the visible and the ultraviolet region of the spectrum in a transparent polymer film, for which a modifier,has been introduced as compared with the film, in which the modifier was not introduced.

In the Table 7 the characteristics of the transparent polymer film according presented invention are shown.

TABLE 7
Characteristics of the transparent polymer film with compositions
and technology according presented invention.

| N/N | Parameters | Properties |
|---|---|---|
| 1. | External view | Transparent |
| | | colorless |
| | | [symbol] [symbol] |
| | | [symbol] |
| | | [symbol] |
| 2. | Index of Refraction Value | 1.49-1.53 |
| 3. | Relative lengthening | 29-32 |
| 4. | Relative lengthening, % | 200-350 |
| 5. | Shelf of the storage | 4-5 |
| | forpolymer, momths. | |
| 6. | The transmission of light in the visible region | 96-98 |
| | and in the in the UV region, %. | |
| | Thickness of the film 2 mm. | |

### Example 4

Testing of the PV modules which are based on monocrystalline Si and the coated with nano structured transparent polymer film according presented invention for the effects of humidity was conducted.

Test conditions were as following:
Relative humidity: (85±3) %.
Temperature: 85° C.
Test duration: 200 hours.

Performances of the modules were determined under following conditions of the measurements:

A halogen lamps simulator with a power of 2 kW was used.

Specific power of the incident radiation was 1000 W/m² (the light exposure measured corresponds 40,000 Lx),

The temperature was 25° C.,

The spectrum was approximated to AM 1.5.

The UV filter was not used.

Results of the testing are presented in Table 8

TABLE 8
Results of testing of PV modules for the effects of high humidity

| Test Duration | 10 hours | 20 hours | 30. hours | 40. hours | 50. hours | 60. hours | 70 hours | 80 hours | 200 hours |
|---|---|---|---|---|---|---|---|---|---|
| Short circuit current in high humidity, A. | 2.86 | 2.84. | 2.85 | 2.87 | 2.83 | 2.84 | 2.83 A | 2.82 | 2.81 |

Initial value: I = 2.88 A

It is known that the parameter most significantly affected by degradation phenomena of the PV module is a short-circuit current. Values of the short circuit current under high humidity test are shown in the Table 8. Differences in short circuit current that were measured were within the margin of error of the equipment used. Photovoltaic modules that were sealed using compounds based on the transparent polymer compositions with the modifier were resistant to the effects of humidity.

### Example 5

Testing the mechanical properties of PV modules. The conditions of the testing were as following:

5.1 Single impact testing

Number of impacts: 100.

5.2. Repeated impact testing (in a shipping container)

Impact frequency: 120 per minute.

Performances of the modules were determined under following conditions of the measurements:

A halogen lamps simulator with a power of 2 kW was used.

Specific power of the incident radiation was 1000 W/m² (the light exposure measured corresponds 40,000 Lx),

The temperature was 25° C.,

The spectrum was approximated to AM 1.5.

The UV filter was not used.

The results of the mechanical properties testing are presented in the Table 9.

Test results show that the solar cell parameters vary within the measurement error (±5%).

TABLE 9
Results of mechanical impact testing of PV modules laminated with
transparent polymer material according presented invention.

| Single Impact Test Number of impacts | 10 | 20 | 30 | 40 | 50 | 60 | 70 | 80 | 100 |
|---|---|---|---|---|---|---|---|---|---|
| Short circuit current, A Initial value was 2.88 A | 2.88 | 2.86 | 2.85 | 2.86 | 2.83 | 2.84 | 2.86 | 2.84 | 2.84 |
| Repeated impact testing (in a shipping container). Duration in min. | 10 | 20 | 30 | 40 | 50 | 60 | | | |
| Short circuit current, A. Initial value was 2.88 A | 2.87 | 2.86 | 2.86 | 2.87 | 2.85 | 2.86 | | | |

It is known that the parameter most significantly affected by degradation phenomena of the PV module is short-circuit current. Results of the test that are presented show that the measured differences in the short circuit current are within the margin of error the equipment (±5%). Photovoltaic modules that were sealed using compounds based on the transparent polymer compositions according presented invention were resistant to the effects of mechanical impact.

### Example 6

Testing the glass-to-glass adhesive properties of the transparent polymer was conducted.

The polymer film dimension was.
thickness of the film: 5 mm
diameter-7 mm

Description of the test is as following. The adhesive strength of polymer compositions, as used for glass-to-glass adhesion, was determined by applying the force needed to move (shift) one piece of glass with respect to another. The tests were conducted at room temperature using the RM-30 test unit. The annex tangential stress was applied at a tensile rate of 100 mm/min. Measurement error was 3% to 5%.

Test results show that the force required breaking the glass—glass bond was between 13 kg/cm² and 17 kg/cm². This force required breaking the glass—glass bond was 2-3 times greater than that of the common Elastosil 1102 prototype material.

### Example 7

In this example the results of the test PV modules which include two solar cells are presented in the Tables 10 and 11.

The test PV modules before and after encapsulation (coating) according presented invention have been conducted. The test of the PV modules which have been laminated with glass have been also conducted. Performances of the modules were determined under following conditions of the measurements. A halogen lamps simulator with a power of 2 kW was used. Specific power of the incident radiation was 1000 W/m² (the light exposure measured corresponds 40,000 Lx), the temperature was 25° C., the spectrum was approximated to AM 1.5.

Performance parameters of the test modules were measured before hermetic sealing and after hermetic sealing and are presented in Tables 10 and 11.

The following parameters were compared:
Open circuit voltage, V_{oc}
Short circuit current, I_{sc}
PV module efficiency, %

TABLE 10
Comparison of the parameters of the PV modules before and after encapsulation with polymer
material according to the present invention and PV modules laminated with glass.

| | Open circuit | Short circuit | | Open circuit | Short circuit | |
|---|---|---|---|---|---|---|
| Type of | voltage, V_{oc} | current, I_{sc}, | | voltage, V_{oc} | current, I_{sc}, | |
| the | before | A before | PV module | after | A after | PV module |
| modules | encapsulation | .encapsulation | efficiency, % | encapsulation | .encapsulation | efficiency, % |
| 41 | 1.2 | 2.2 | 14.1 | 1.23 | 2.42 | 15.9 |
| 44 | 1.2 | 2.2 | 14.1 | 1.23 | 2.42 | 15.9 |
| 43 | 1.2 | 2.2 | 14.1 | | | |
| 45 | 1.2 | 2.2 | 14.1 | 1.1 | 2.1 | 12.34 |

A halogen lamps simulator with a power of 2 kW was used. Specific power of the incident radiation was 1000 W/m² (the light exposure measured corresponds 40,000 Lx). UV filter was used.

TABLE 11
Comparison of the parameters of the PV modules before and after encapsulation with polymer
material according to the presented invention and PV modules laminated with glass.

| | Open circuit | Short circuit | | Open circuit | Short circuit | |
|---|---|---|---|---|---|---|
| Type of | voltage, V_{oc} | current, I_{sc}, | | voltage, V_{oc} | current, I_{sc}, | |
| the | before | A before | PV module | after | A after | PV module |
| modules | encapsulation | .encapsulation. | efficiency, % | encapsulation | .encapsulation | efficiency, % |
| 41 | 1.22 | 2.9 | 18.9 | 1.25 | 3.2 | 21.37 |
| 44 | 1.23 | 2.9 | 19.0 | 1.25 | 3.15 | 21.0 |
| 43 | 1.22 | 2.9 | 18.9 | | | |
| 45 | 1.22 | 2.9 | 18.9 | 1.1 | 2.8 | 6.45 |

A halogen lamps simulator with a power of 2 kW was used. The light exposure measured corresponds to 40,000 Lx. UV filter was no used.
PV modules No. 41 and 44: series connection of two solar cells which are encapsulated by nanostructured transparent polymer according the invention that is presented.
PV module No. 43: series connection of two solar cells without polymer and without the glass (initial solar cells)
PV module No. 45: series connection of two solar cells which are laminated with glass. The thickness of the glass is 1.7 mm.

### Example 8

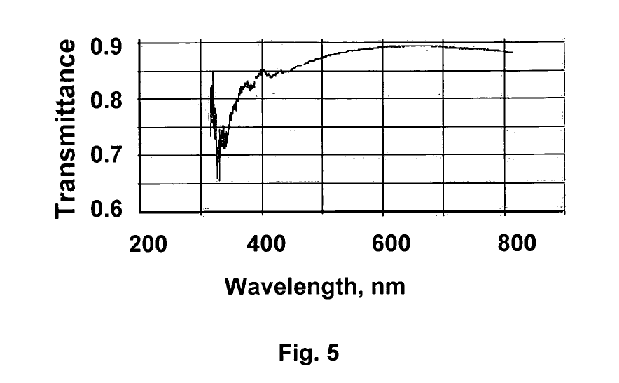

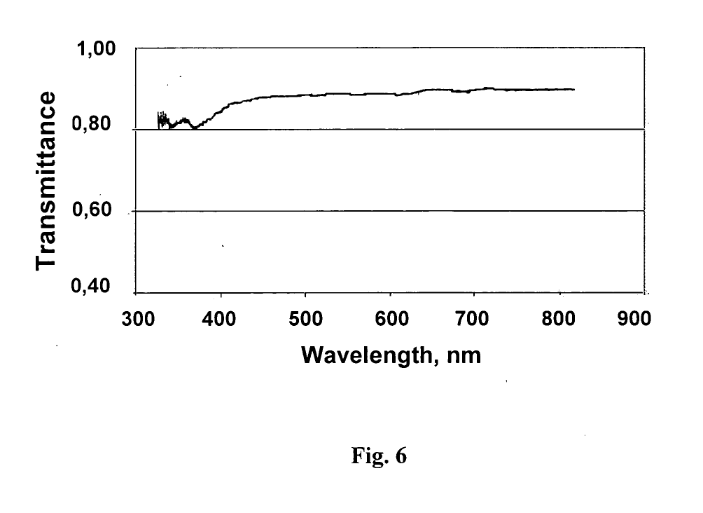

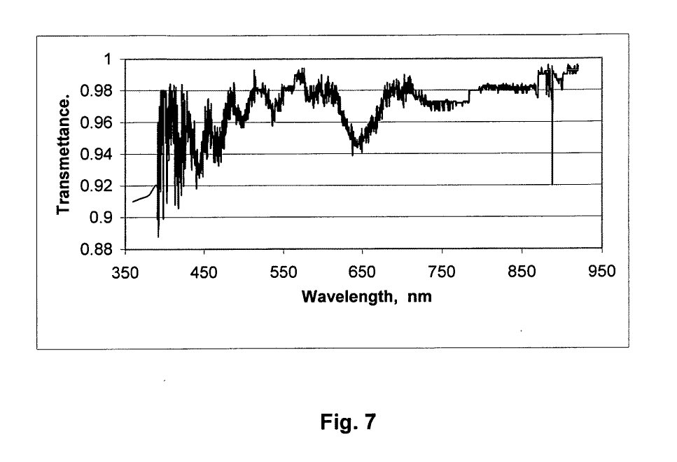

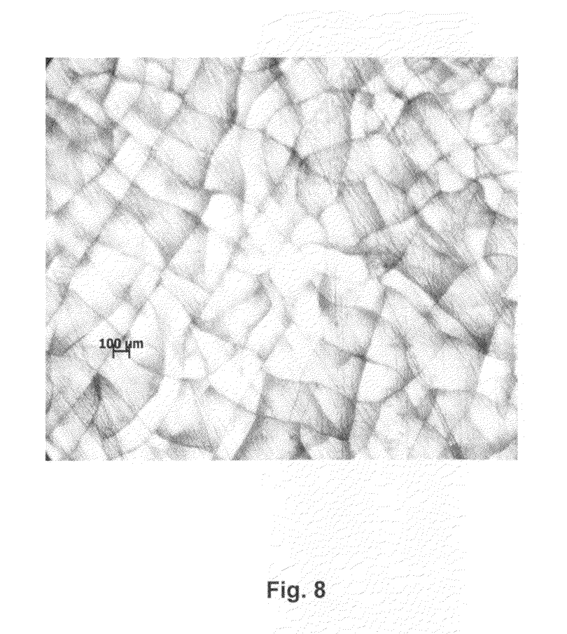

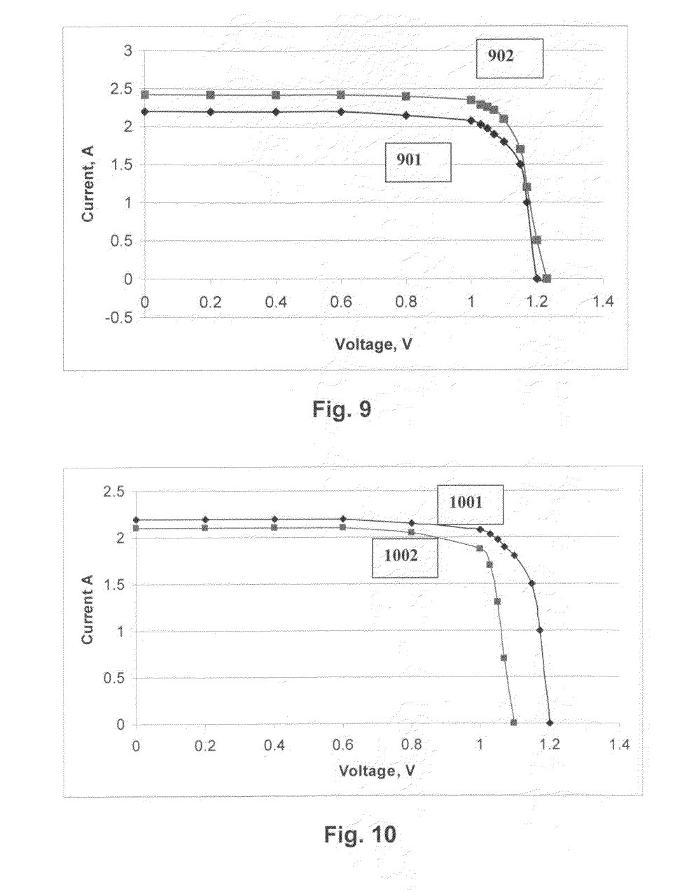

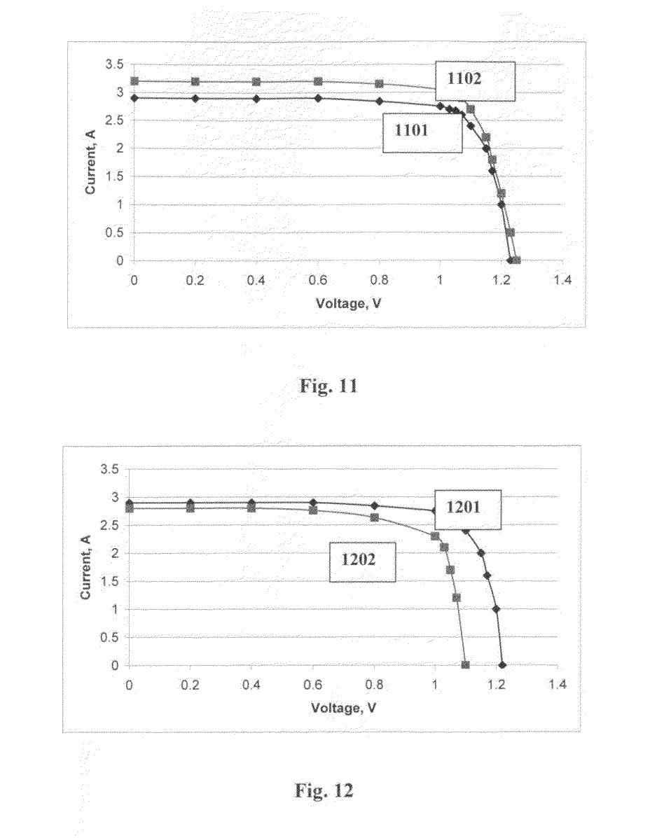

In the current examples the transmittance of the nano structured transparent polymer film are presented. The properties of the flexible optically transparent cover made from organic materials according to the presented invention (FIG. 7), the organic materials with the same compositions with the exception of a modifier (FIG. 6) and a quartz glass plate that is used for encapsulation of photovoltaic cells for space applications (FIG. 5) are compared in terms of transmittance as a function of wavelength. Results that presented in FIGS. 5, 6 and 7 confirm that in the ultra-violet wavelength range (less than 380 nanometers) the polymer covering has a much greater transmittance as compared with a quartz glass plate. The polymer that includes modifier according presented invention has even higher properties. As a result, the conversion efficiency of PV modules that are coated/sealed with the polymer layer according to the present invention is higher as compared with the PV modules laminated with glass.

Closure

While various embodiments of the present invention have been shown and described, it will be apparent to those skilled in the art that many changes and modifications may be made without departing from the invention in its broader aspects. The appended claims are therefore intended to cover all such changes and modifications as fall within the true spirit and scope of the invention.

What is claimed is:

1. Flexible optically transparent nano structured polymer material high level of the adhesive to the surface of the optical devices to cover an optical devices thereby forming an encapsulating layer over the optical device for protecting the optical device from humidity and UV undesired lights, said that this polymer material is based on the composition comprising:
derivatives of polyurethanes synthesized on the basis of the mixture of olyglycoladipates having different compositions, and molecular weight, and of aliphatic diisocyanates;
multifunctional hydroxyl based a hardening agent;
antistatic additives; and
low-molecular esters having a general formula of: R—C(O)—OR′, where R is at least one of CH₃, C₂H₅ and R′ is at least one of CH₃, C₂H₅, C₄H₉, C₅H₁₁ acting as modifiers having wherein modifiers have an active chemical affinity to the initial components of said polymer compositions connected by intermolecular hydrogenous bonds both with the basis of compound and with hardeners, thereby forming in said composition nano domain and micro-domains and clusters of various dimensions and configurations located in a predetermined order in said polymer material wherein said nano domail and micro-domains and clusters functionally form micro lenses to concentration of light on the optical device and strengthen wave of optical radiation.

2. A flexible optically transparent nano structured polymer material as set forth in claim 1, wherein said micro-domains and clusters formed in the volume of said polymer material have a size from 5 to 150 micron.

3. A flexible optically transparent nano structured polymer material as set forth in claim 1, wherein said nano domain and clusters formed in the volume of said polymer material have a size from 20 to 100 nm.

4. A flexible optically transparent nano structured polymer material as set forth in claim 1, wherein said polymeric encapsulating layer is made of a compound of derivatives of polyurethanes that are based on polyurethane oligomers.

5. A flexible optically transparent nano structured polymer material as set forth in claim 1, wherein said polymeric encapsulating layer is made of a compound of derivatives of polyurethanes that are based on epoxy-urethane oligomers.

6. A composition as set forth in claim 1, wherein as a components for synthesis of forpolymer or oligomer as the polyethyleneglycoladipinat the compounds of polyethyleneglycoladipinat of molecular weight 800-2000 are used and also as aliphatic diisocyanates is used hexamethylendiisocyanate

7. A composition as set forth in claim 1, wherein as a hardening agent from the class of bi-and trifunctional hydroxyl compounds of the mixture of trimethylpropane and glycerin is used.

8. A flexible optically transparent nano structured polymer material as set forth in claim 1, wherein said composition is includes metal dopants, wherein the said metal dopants are made from materials which include the ions of at least one of Pb, Co, Zn, Cu or made from metal powder.

9. A flexible optically transparent nano structured polymer material as set forth in claim 1, wherein said encapsulating layer is formed as a result of the flowing the composition onto the front face surface of the optical device.

10. A flexible optically transparent nano structured polymer material as set forth in claim 1, wherein said encapsulating layer is formed as a result of the dispersion of the composition onto on the front-face surface of the optical device.

11. Flexible optically transparent nano structured polymer material as set forth in claim 1, wherein the optical devices where the forming an encapsulating layer are include the PV modules, optical devices with a complex configuration, concentrated systems for PV modules including plastic lenses, the Fresnel lens's, in microreplication, an interlayer between glass and bullet-proof windows.

12. A photovoltaic module comprising:
a cell unit having a plurality of photovoltaic cells connected in series-parallel relationship relative one another,
a substrate with insulating layer facing said cell unit, said substrate connected to said photovoltaic cells by an adhesive material connected to back surface of said photovoltaic cells, and
said photovoltaic cells having a front surface exposed to with the incident light-including an encapsulating layer of the flexible optically transparent nano structured polymer material for protecting said photovoltaic cells from humidity and UV undesired lights, said flexible optically transparent nano structured polymer material based on the composition comprising: derivatives of polyurethanes synthesized on the basis of the mixture of polyglycoladipates having different compositions, and molecular weight, and aliphatic diisocyanates, multifunctional hydroxyl based a hardening agent, antistatic additives, and the modifier presenting low-molecular esters having a general formula of: R—C(O)—OR′, where R is at least one of CH₃, C₂H₅ and R′ is at least one of CH₃, C₂H₅, C₄H₉, C₅H₁₁ acting as modifiers having an active chemical affinity to the initial components of said polymer compositions connected by intermolecular hydrogenous bonds both with the basis of compound and with hardeners thereby forming in said composition nano particles and micro-domains and clusters of various dimensions and configurations located in a predetermined order in said polymer material wherein said nano particles and micro-domains and clusters functionally form micro lenses to concentration of light on the optical device and strengthen wave of optical radiation.

13. A photovoltaic module as in claim 12, wherein each of said photovoltaic cells is made of at least one of mono-crystalline silicon, multi-crystalline silicon, amorphous silicon, nano-crystalline silicon or non-silicon materials, including dye-sensitized solar cell and organic solar cells.

14. A photovoltaic module as in claim 12, wherein each in this module of said photovoltaic cells is based on CIGS ((copper indium gallium selenide)) and at standard conditions (llumination: 40000 Lx; λₘₐₓ=550 . . . 650 nm) open circuit voltage of said photovoltaic module is higher as 9-14% and more as compared with PV modules that are based on CIGS and does not laminated with any materials).

15. A photovoltaic module as in claim 12, wherein each of said photovoltaic module is based on CIGS (copper indium gallium selenide) and at conditions illumination less then 1200 Lx, λₘₐₓ=380 . . . 450 nm the open circuit voltage of said photovoltaic module is higher as 55-75% and more as compared with PV modules that are based on CIGS and does not laminated with any materials.

16. A photovoltaic module as in claim 12, wherein said substrate includes a metal sheet covered by an electrically insulating layer and aluminum foil is used as a metal, and an anodized layer of said aluminum serves as an insulator.

17. A photovoltaic module as in claim 12, wherein said substrate includes a polymeric sheet coated by metallic layers for providing electrical contact.

18. A photovoltaic device as in claim 12, wherein a transparent film of conductive oxide metal is affixed between the flexible optically transparent cover and front-face surface of the photovoltaic cell module.

19. A photovoltaic module as in claim 12, wherein said encapsulating layer is further defined by a film presenting a flat coat surface morphology or relief/crinkle coat surface morphology presenting a random rounded ridge and valley structure wherein the radii of curvature of the concave and convex features of the structure are between approximately 0.3 mm and 2.5.mm.
